(19) United States
(12) Patent Application Publication
(10) Pub. No.: US 2008/0251936 A1
(43) Pub. Date: Oct. 16, 2008

(54) SEMICONDUCTOR DEVICE

(76) Inventor: Hiroshi KURODA, Tokyo (JP)

Correspondence Address: MILES & STOCKBRIDGE PC, 1751 PINNACLE DRIVE, SUITE 500, MCLEAN, VA, 22102-3833, US

(21) Appl. No.: 11/969,220

(22) Filed: Jan. 3, 2008

(30) Foreign Application Priority Data
Jan. 15, 2007 (JP) 2007-005574

(51) Int. Cl. H01L 23/49

(52) U.S. Cl. 257/777; 257/E23.024

(57) ABSTRACT

The generation of a wire bonding defect is reduced in the semiconductor device in which semiconductor chips are laminated. A wiring substrate, the first memory chip by which face-up mounting is done via the first filmy adhesive on the wiring substrate, the second memory chip by which face-up mounting is done via the second filmy adhesive on the first memory chip, and the microcomputer chip by which face-up mounting is done via the third filmy adhesive on the second memory chip are included. Since the third filmy adhesive adhered to the microcomputer chip of the highest stage is the thinnest, at the time of wire bonding of the microcomputer chip, the influence to the ultrasonic wave and load of wire bonding by softening of a filmy adhesive which takes place with the heat can be reduced, and lowering of wire bonding property can be suppressed.

### CROSS-REFERENCE TO RELATED APPLICATION

The present application claims priority from Japanese patent application No. 2007-5574 filed on Jan. 15, 2007, the content of which is hereby incorporated by reference into this application.

1. Field of the Invention

The present invention relates to a semiconductor device, and particularly relates to a semiconductor device on which a plurality of semiconductor chips are laminated, and which is assembled by wire bonding.

2. Description of the Background Art

In System In Package (SIP), there is technology of having a stack structure which accumulated and mounted two memory chips on a main surface of a wiring substrate, accumulated and mounted a microcomputer chip in the upper part further, and sealed these chips with mold resin (for example, refer to Patent Reference 1).

[Patent Reference 1] Japanese patent laid-open No. 2004-228323 (FIG. 22)

### SUMMARY OF THE INVENTION

As an example of a semiconductor device which has a plurality of semiconductor chips, the semiconductor device called SIP (System In Package) in which a semiconductor chip which has a data-processing function (it is also henceforth called a microcomputer chip), and a semiconductor chip (it is also henceforth called a memory chip) which has a memory circuit are mounted by laminating on a wiring substrate is known.

Although further thickness reduction and advanced features are demanded also in SIP, the cost rising must be suppressed. Then, as one means of cost rising suppression, by making all electric connections with a wiring substrate by wire bonding, reduction of cost can be aimed at comparing with the case where flip chip connection of the chip of the first stage is made. For example, reduction of cost can be aimed at by doing multi stage lamination of a plurality of semiconductor chips on a wiring substrate, and electrically connecting each semiconductor chip and the wiring substrate by wire bonding.

In this case, as for each semiconductor chip to be laminated, in order to perform wire bonding, all of each stages become face-up mounting so that the main surface in which the surface electrode is formed may become the identical direction to a main surface (a front surface, a chip mounting surface) of the wiring substrate. The surface electrode of the main surface of the semiconductor chip of the first stage is arranged on the outside of the semiconductor chip of the second stage when laminating the semiconductor chip of the second stage on the semiconductor chip of the first stage (bottom) by face-up mounting. The distance of the surface electrode of the semiconductor chip of the first stage and the end portion of the semiconductor chip of the second stage becomes very short in the case. Therefore, when using a paste state binder as a die bonding material, the inconvenience that the binder which overflowed from the semiconductor chip of the second stage will cover the surface electrode of the semiconductor chip of the first stage happens.

So, when laminating semiconductor chips, it is effective to adopt a filmy adhesive (henceforth, it is also called DAF (Die Attach Film)) as a die bonding material. The distance of the end portion of a semiconductor chip and the bonding lead (electrode) formed on the wiring substrate also becomes near with the miniaturization of a semiconductor device. Therefore, it is effective to mount on a wiring substrate via DAF also about the semiconductor chip of the first stage.

The die strength of a semiconductor chip can be improved by using DAF. As for the semiconductor chip, thickness reduction is demanded in connection with the thickness reduction of a semiconductor device. Therefore, the die strength of the chip tends to fall. However, since the semiconductor chip which became thin can be reinforced with using DAF from the back surface side, the die strength of the chip can be improved.

However, the SIP type semiconductor device mounts the semiconductor chips of a different kind, as described above. Therefore, when the semiconductor chip of different size is laminated, near the end portion of the semiconductor chip at the side of the upper row may do an overhang (push out) to the lower stage chip. This is because of the reason of laminating the enlarged semiconductor chip by the realization of high-capacity of a memory chip and the increasing of pin count of the microcomputer chip accompanying advanced features of SIP in recent years. Here, the memory chip is SDRAM (Synchronous Dynamic Random Access Memory) of high-speed correspondence which adopted the DDR (Double Date Rate) method with speeding up of a system, for example. A DDR system is a method which uses both times at the time of a rise and drop of an external clock signal when taking a synchronization between each circuit, and the size of the semiconductor chip also becomes large.

To explain in detail, when for example semiconductor chips of three different sizes, such as one microcomputer chip and two memory chips, are laminated, since face-up mounting will be done, respectively and it is necessary to expose the surface electrode of each semiconductor chip when all the chips are wire connection, a comparatively small semiconductor chip will be mounted as it goes to the upper row. Here, in the case of a memory chip with relatively few surface electrodes, a plurality of surface electrodes are arranged only at one side, or two sides of the memory chip. Therefore, in the case of laminating other memory chip on a memory chip, when laminating them by shifting the side in the memory chip of the upper row where the surface electrodes have been arranged against the side in the memory chip of the lower stage where the surface electrodes have been arranged, it is possible to mount them while exposing the surface electrodes of each memory chip easily.

However, in the case of making a comparatively big memory chip and a microcomputer chip intermingled and laminating them, it is desirable for a microcomputer chip to be arranged to the highest stage by taking it into consideration to perform wire bonding to all four sides, since the surface electrodes are formed in the edge part of four sides of the main surface by the increasing of pin count as for the microcomputer chip.

In consideration of these, the biggest memory chip is mounted in the first stage (bottom), and, as a result, a memory chip smaller than the memory chip of the bottom is mounted in the second stage (middle). And a microcomputer chip is mounted in the third stage (highest stage). In such a case, it may become the structure called an overhang that near the end portion of the microcomputer chip of the highest stage is pushed out from the memory chip of the middle. In the case, the surface electrode is arranged in the part which pushed out of a microcomputer chip, and wire bonding is performed to the surface electrode of this part that pushed out.

This time, in the semiconductor device which does wire bonding of each semiconductor chip laminated by three stages via DAF with an ultrasonic thermocompression bonding method, the inventor of the present invention found out the problem at the time of wire bonding of the semiconductor chip in which the part where the surface electrode was formed overhangs from the semiconductor chip of the lower stage especially as follows.

For example, in 3 stages of chip lamination and in the structure where a part of the semiconductor chip of the third stage (highest stage) is overhanging to the semiconductor chip of the second stage, all the DAF of the 1-3rd stage soften under the influence of the heat of the wire-bonding step. Softening of DAF will sink a semiconductor chip easily according to the ultrasonic wave and load in the wire-bonding step. As a result, since the semiconductor chip is not stabilized, and it becomes difficult for an ultrasonic wave to travel to the surface electrode of a semiconductor chip, a wire bonding defect occurs. The back surface side of the surface electrode of the semiconductor chip of the third stage (highest stage) is what is called in a hollow state which is not supported at all. Therefore, the ultrasonic wave in the wire-bonding step becomes further difficult to be transmitted, bonding property of a wire gets worse, and wire peeling is caused.

As a result, the problem of a wire bonding defect occurs and the reliability of the semiconductor device falls.

SIP of the structure where one microcomputer chip and two memory chips are laminated is disclosed by the Patent Reference 1 (Japanese patent laid-open No. 2004-228323). However, there is neither the description about the problem that DAF softens under the influence of the heat in the wire-bonding step, and the problem of the wire bonding defect in the surface electrode of the overhang part of the chip, nor the description about the solving means. Therefore, with the structure described to the Patent Reference 1, it is imagined that the same problem generates.

A purpose of the present invention is to offer the technology which can improve the reliability of a semiconductor device.

A purpose of the present invention is to offer the technology in which the generation of a wire bonding defect can be reduced, in the semiconductor device with which the semiconductor chip is laminated via DAF.

Other purpose of the present invention is to offer the technology in which the generation of a wire bonding defect can be reduced in the semiconductor device with which semiconductor chips are laminated via DAF and the semiconductor chips with which the surface electrode is formed in the currently overhanging part are laminated.

The above-described and the other purposes and novel features of the present invention will become apparent from the description herein and accompanying drawings.

Of the inventions disclosed in the present application, typical ones will next be summarized below briefly

Namely the present invention includes a wiring substrate having a main surface and a back surface, a plurality of semiconductor chips mounted by laminating over the main surface of the wiring substrate, a filmy adhesive adhered to a back surface of each of the semiconductor chips, a plurality of wires, and a plurality of external terminals formed in the back surface of the wiring substrate, wherein the filmy adhesive adhered over the back surface of the semiconductor chip of the highest stage is the thinnest among the filmy adhesives of the back surface of each of the semiconductor chips.

Advantages achieved by some of the most typical aspects of the invention disclosed in the present application will be briefly described below.

Since the filmy adhesive adhered to the back surface of the semiconductor chip of the highest stage is the thinnest among the filmy adhesives of the back surface of each of a plurality of semiconductor chips, the influence to the ultrasonic wave and load of wire bonding by softening of the filmy adhesive which happens with the heat can be reduced at the time of wire bonding of the semiconductor chip of the highest stage. As a result, lowering of wire bonding property can be suppressed, the generation of wire peeling can be prevented, and the generation of a wire bonding defect can be reduced.

### BRIEF DESCRIPTION OF THE DRAWINGS

FIG. 1 is a cross-sectional view showing an example of the structure of the semiconductor device of Embodiment 1 of the present invention;

FIG. 2 is a plan view penetrating a sealing body and showing an example of the fine structure of the semiconductor device shown in FIG. 1;

FIG. 3 is a cross-sectional view showing an example of the structure cut along the A-A line of FIG. 2;

FIG. 4 is a partially expanded cross-sectional view expanding and showing an example of the structure of the section C shown in FIG. 3;

FIG. 5 is a cross-sectional view showing an example of the structure cut along the B-B line of FIG. 2;

FIG. 6 is a partially expanded cross-sectional view expanding and showing an example of the structure of the section D shown in FIG. 5;

FIG. 7 is a plan view penetrating a sealing body and showing an example of a wiring state of the first stage chip in the semiconductor device shown in FIG. 2;

FIG. 8 is a cross-sectional view showing an example of the structure cut along the A-A line of FIG. 7;

FIG. 9 is a cross-sectional view showing an example of the structure cut along the B-B line of FIG. 7;

FIG. 10 is a plan view penetrating a sealing body and showing an example of a wiring state of the second stage chip in the semiconductor device shown in FIG. 2;

FIG. 11 is a cross-sectional view showing an example of the structure cut along the A-A line of FIG. 10;

FIG. 12 is a cross-sectional view showing an example of the structure cut along the B-B line of FIG. 10;

FIG. 13 is a plan view penetrating a sealing body and showing an example of a wiring state of the first stage chip and the second stage chip in the semiconductor device shown in FIG. 2;

FIG. 14 is a cross-sectional view showing an example of the structure cut along the A-A line of FIG. 13;

FIG. 15 is a cross-sectional view showing an example of the structure cut along the B-B line of FIG. 13;

FIG. 16 is a plan view penetrating a sealing body and showing an example of a wiring state of the third stage chip in the semiconductor device shown in FIG. 2;

FIG. 17 is a cross-sectional view showing an example of the structure cut along the A-A line of FIG. 16;

FIG. 18 is a cross-sectional view showing an example of the structure cut along the B-B line of FIG. 16;

FIG. 19 is a circuit block picture showing an example of the connectable state of three semiconductor chips in the semiconductor device shown in FIG. 2;

FIG. 20 is a manufacturing flow picture showing an example of the assembly procedure of the semiconductor device of FIG. 2;

FIG. 21 is a cross-sectional view showing an example of a wire-bonding state of the third stage chip in the assembly of the semiconductor device shown in FIG. 2;

FIG. 22 is a partially expanded cross-sectional view expanding and showing an example of the structure of the section A of FIG. 21;

FIG. 23 is a cross-sectional view showing an example of the structure of the semiconductor device of Embodiment 2 of the present invention;

FIG. 24 is a plan view penetrating a sealing body and showing an example of the fine structure of the semiconductor device shown in FIG. 23;

FIG. 25 is a cross-sectional view showing an example of the structure cut along the A-A line of FIG. 24;

FIG. 26 is a cross-sectional view showing an example of the structure cut along the B-B line of FIG. 24;

FIG. 27 is a plan view penetrating a sealing body and showing an example of a wiring state of the first stage chip in the semiconductor device shown in FIG. 24;

FIG. 28 is a cross-sectional view showing an example of the structure cut along the A-A line of FIG. 27; and

FIG. 29 is a cross-sectional view showing an example of the structure cut along the B-B line of FIG. 27.

### DETAILED DESCRIPTION OF THE PREFERRED EMBODIMENTS

In the following embodiments, except the time when especially required, explanation of identical or similar part is not repeated in principle.

Further, in the below-described embodiments, a description will be made after divided into plural sections or in plural embodiments if necessary for convenience sake. These plural sections or embodiments are not independent each other, but in relation such that one is a modification example, details or complementary description of a part or whole of the other one unless otherwise specifically indicated.

And, in the below-described embodiments, when a reference is made to the number of elements (including the number, value, amount and range), the number is not limited to a specific number but may be equal to or greater than or less than the specific number, unless otherwise specifically indicated or principally apparent that the number is limited to the specific number.

Hereafter, embodiments of the invention are explained in detail based on drawings. Incidentally in all the drawings for describing the embodiments, members of a like function will be identified by like reference numerals and overlapping descriptions will be omitted.

### Embodiment 1

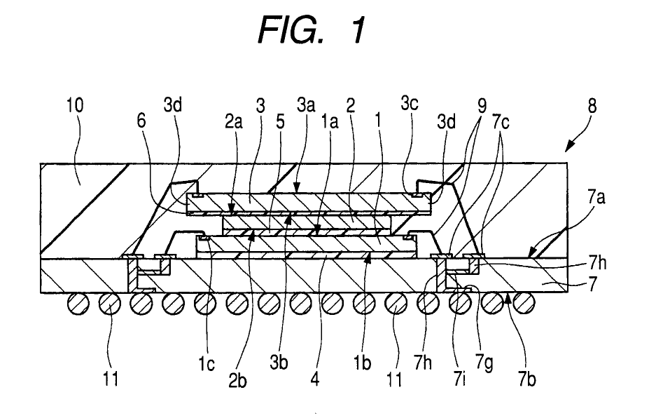

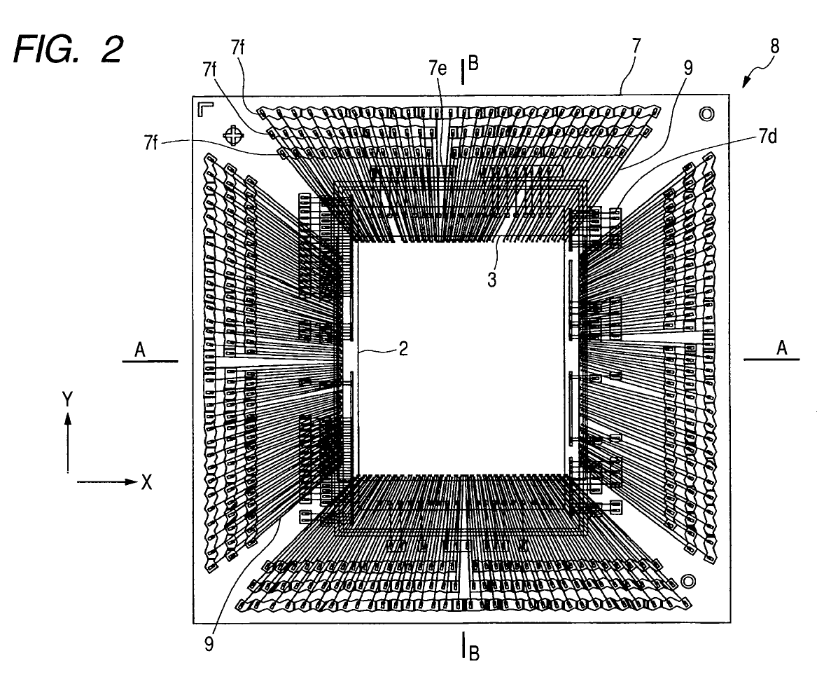

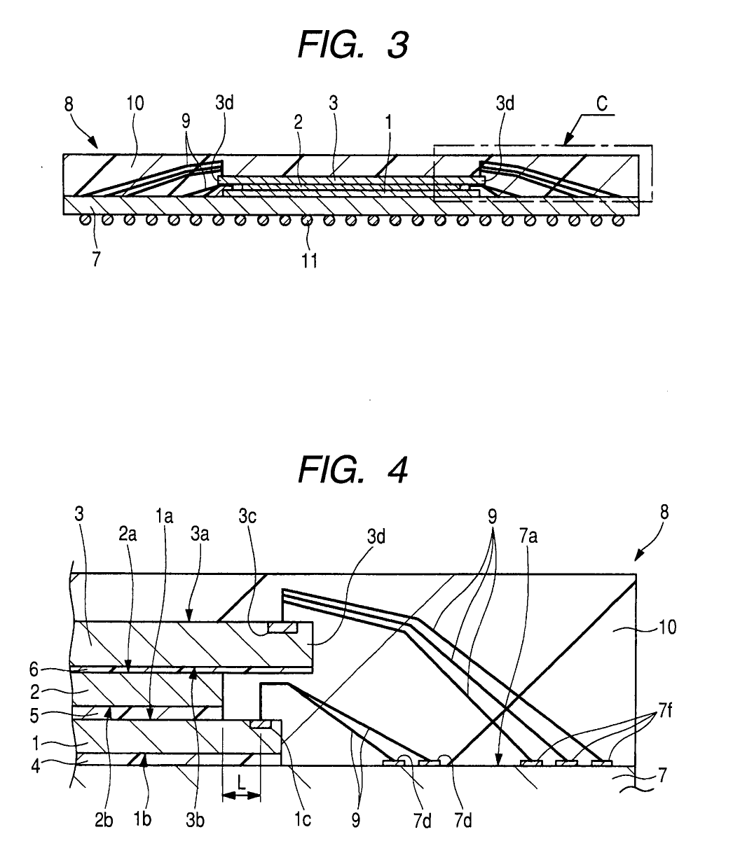

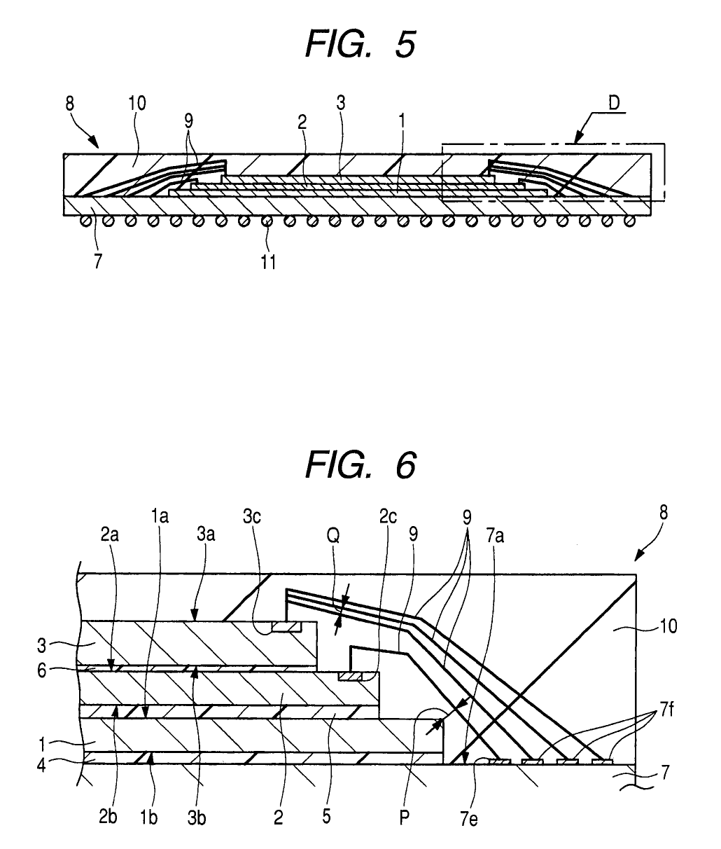

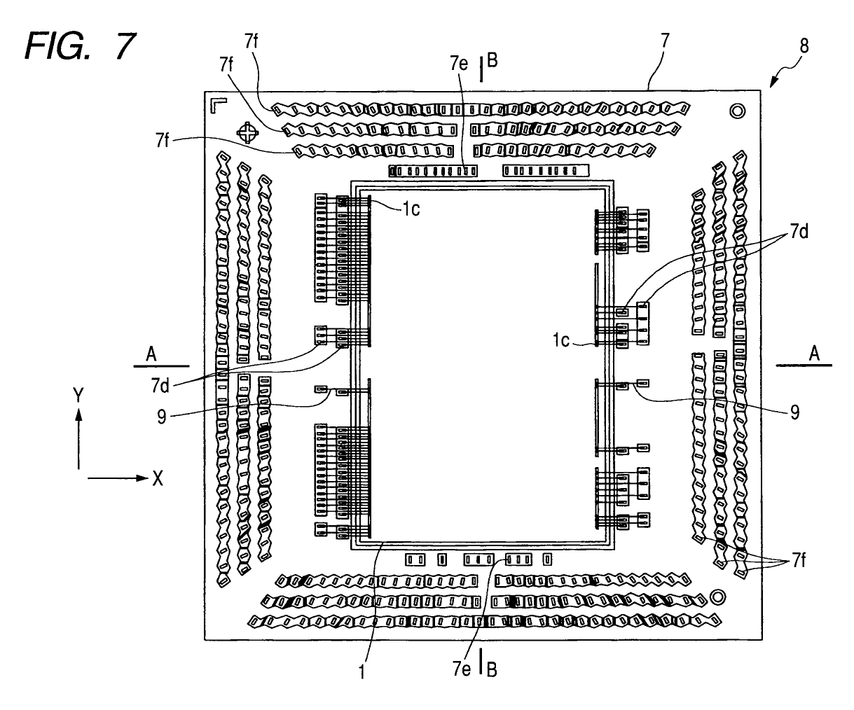

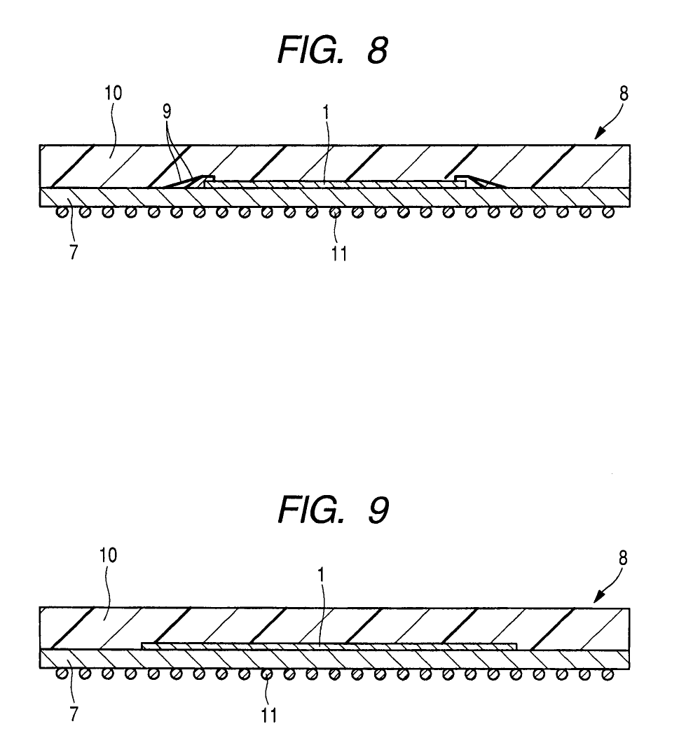

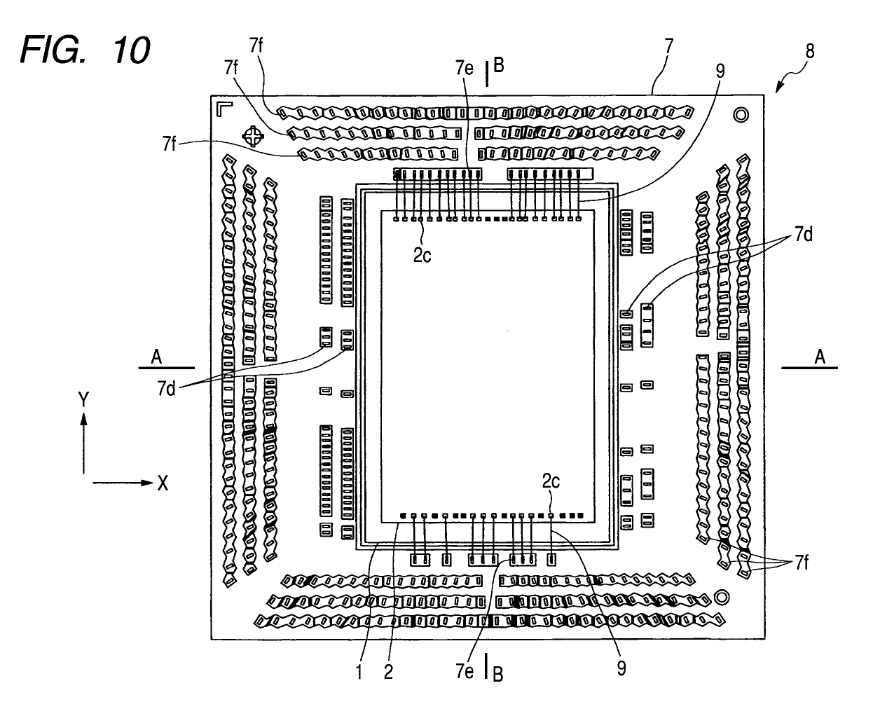

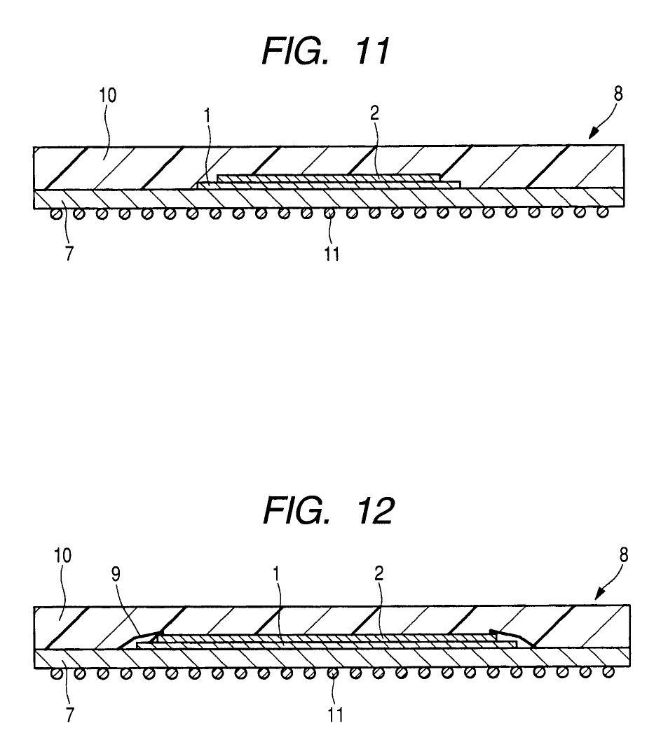

FIG. 1 is a cross-sectional view showing an example of the structure of the semiconductor device of Embodiment 1 of the present invention, FIG. 2 is a plan view penetrating a sealing body and showing an example of the fine structure of the semiconductor device shown in FIG. 1, FIG. 3 is a cross-sectional view showing an example of the structure cut along the A-A line of FIG. 2, FIG. 4 is a partially expanded cross-sectional view expanding and showing an example of the structure of the section C shown in FIG. 3, FIG. 5 is a cross-sectional view showing an example of the structure cut along the B-B line of FIG. 2, and FIG. 6 is a partially expanded cross-sectional view expanding and showing an example of the structure of the section D shown in FIG. 5. And, FIG. 7 is a plan view penetrating a sealing body and showing an example of a wiring state of the first stage chip in the semiconductor device shown in FIG. 2, FIG. 8 is a cross-sectional view showing an example of the structure cut along the A-A line of FIG. 7, and FIG. 9 is a cross-sectional view showing an example of the structure cut along the B-B line of FIG. 7. Further, FIG. 10 is a plan view penetrating a sealing body and showing an example of a wiring state of the second stage chip in the semiconductor device shown in FIG. 2, FIG. 11 is a cross-sectional view showing an example of the structure cut along the A-A line of FIG. 10, and FIG. 12 is a cross-sectional view showing an example of the structure cut along the B-B line of FIG. 10.

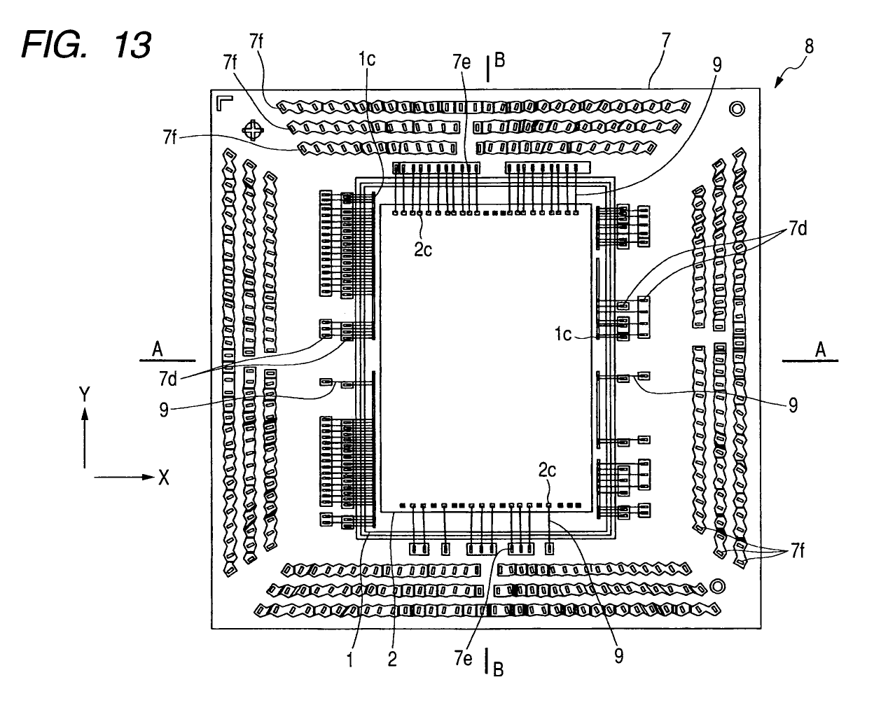

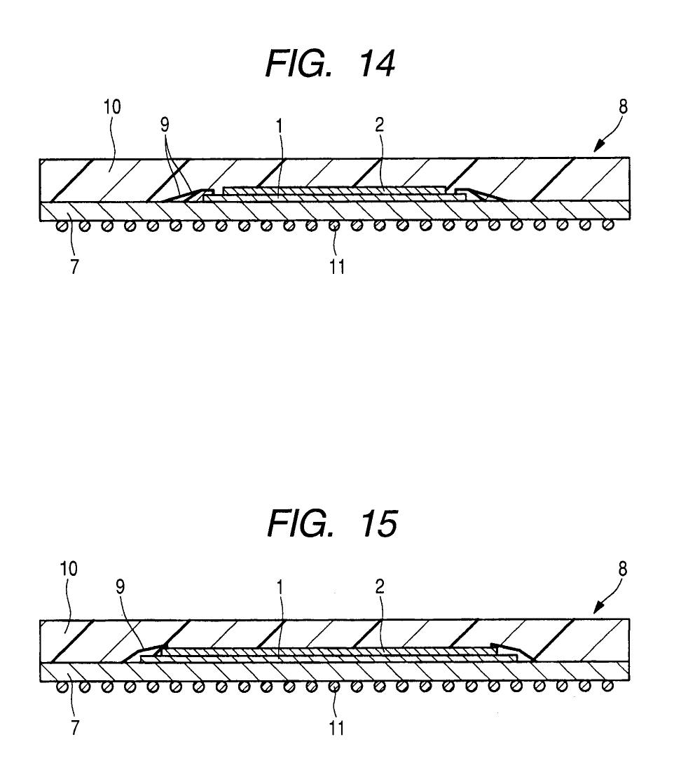

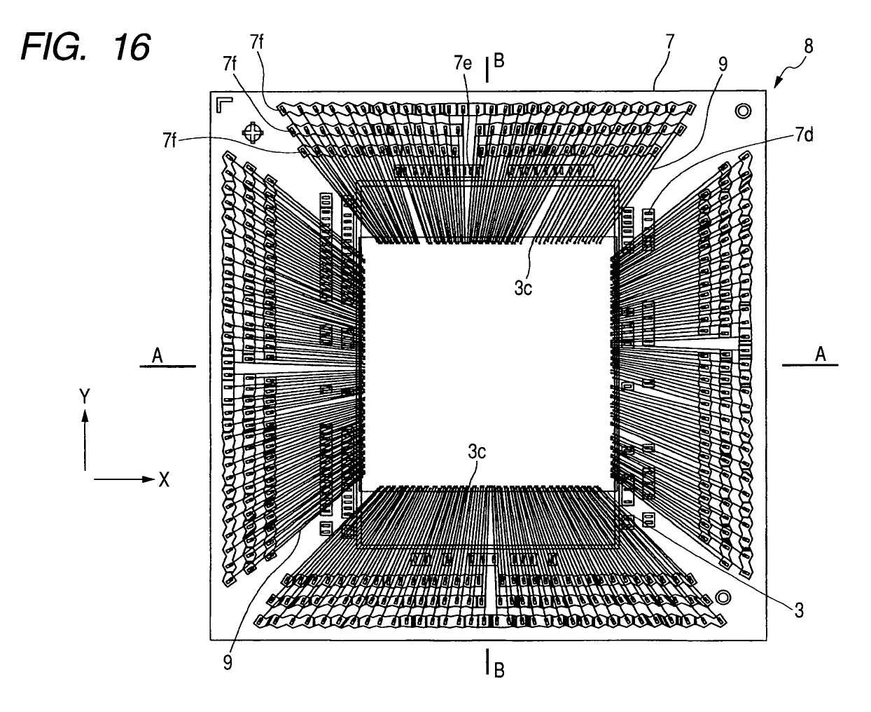

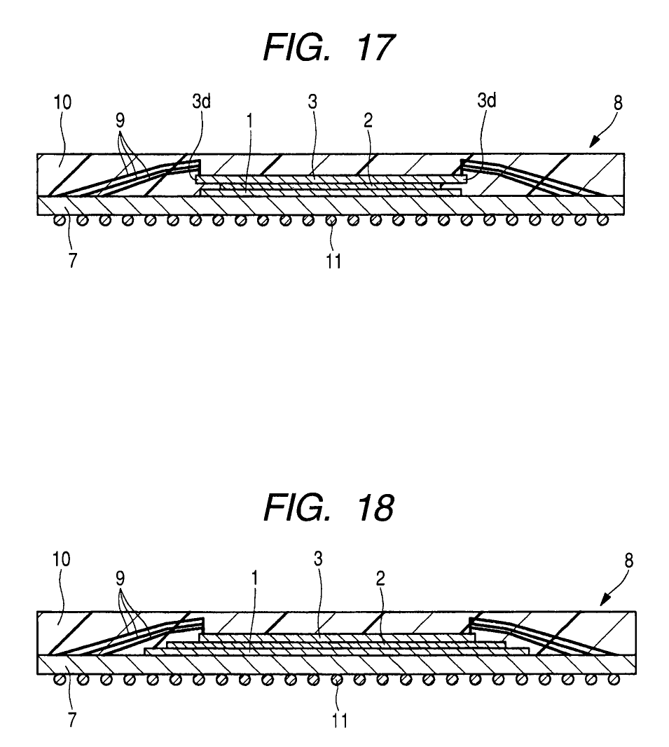

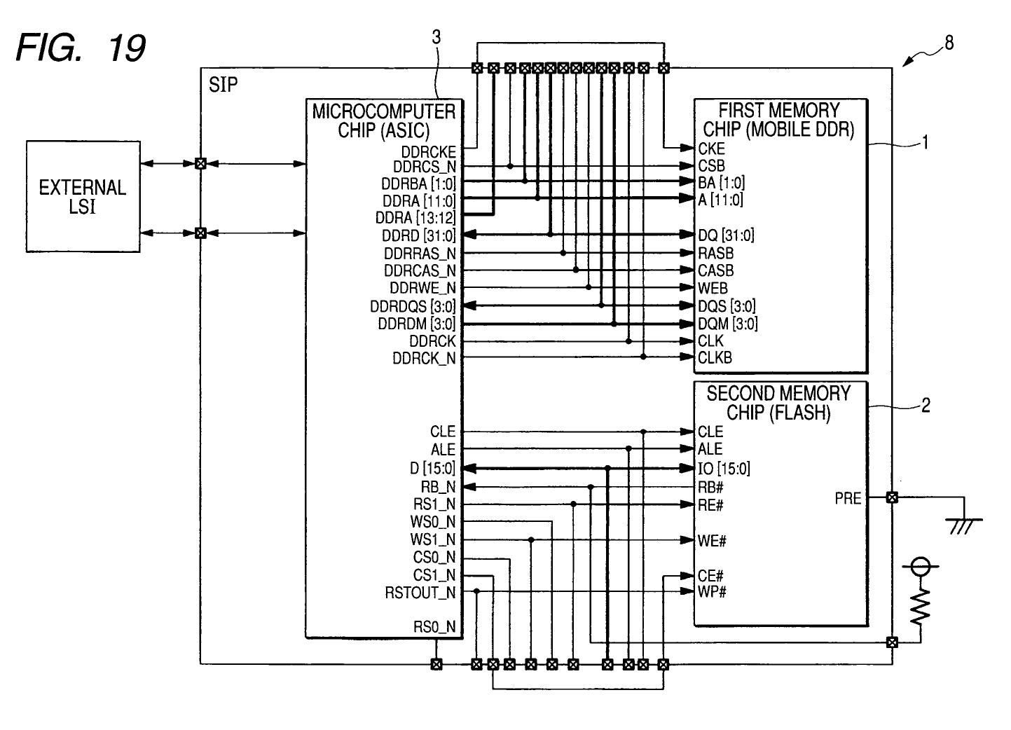

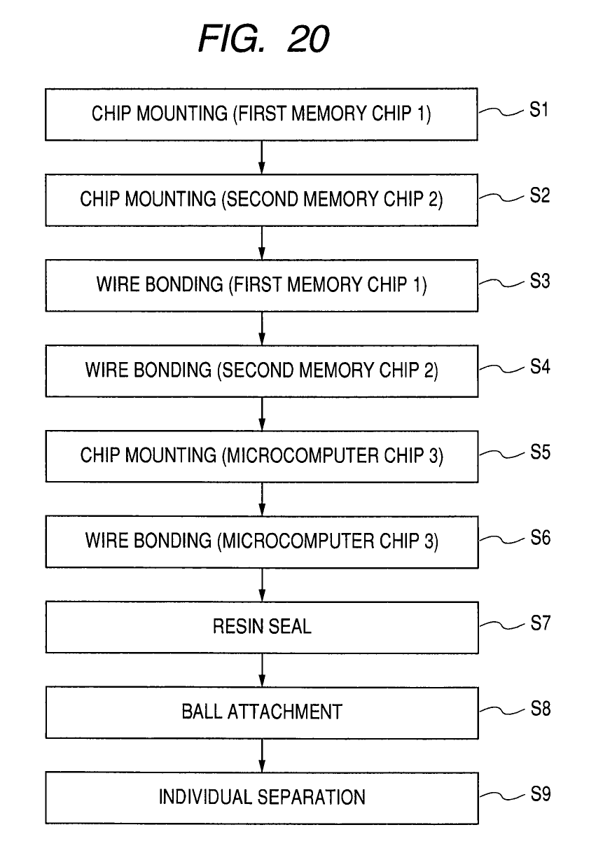

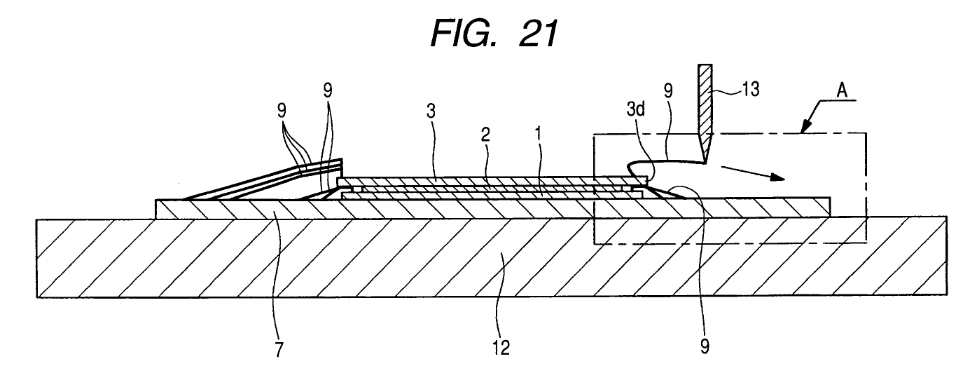

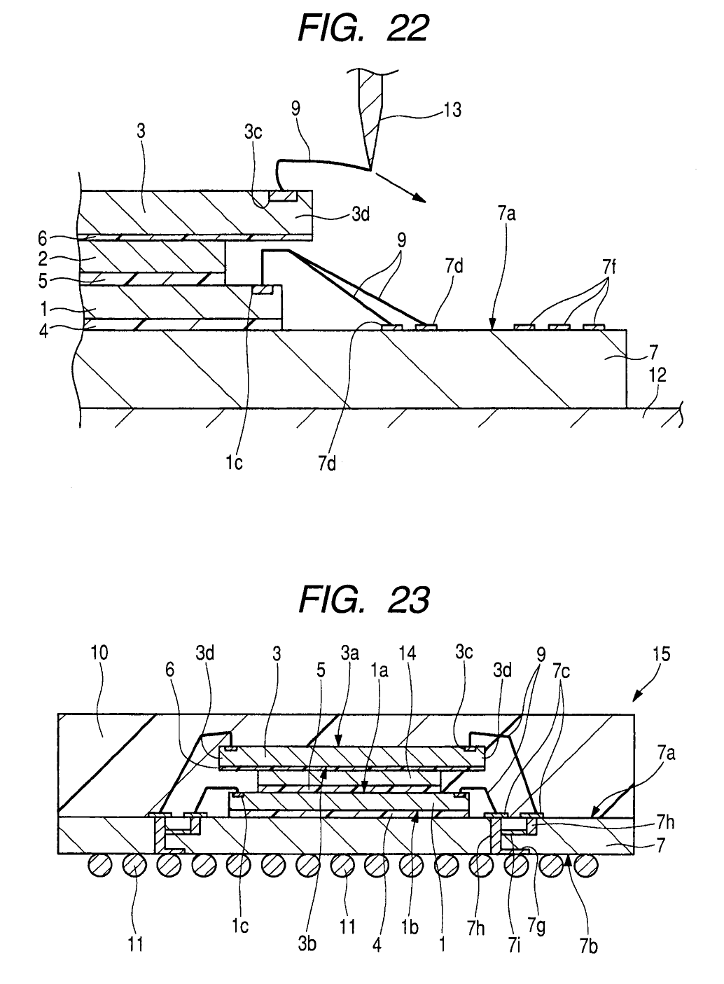

And, FIG. 13 is a plan view penetrating a sealing body and showing an example of a wiring state of the first stage chip and the second stage chip in the semiconductor device shown in FIG. 2, FIG. 14 is a cross-sectional view showing an example of the structure cut along the A-A line of FIG. 13, and FIG. 15 is a cross-sectional view showing an example of the structure cut along the B-B line of FIG. 13. Further, FIG. 16 is a plan view penetrating a sealing body and showing an example of a wiring state of the third stage chip in the semiconductor device shown in FIG. 2, FIG. 17 is a cross-sectional view showing an example of the structure cut along the A-A line of FIG. 16, FIG. 18 is a cross-sectional view showing an example of the structure cut along the B-B line of FIG. 16, and FIG. 19 is a circuit block picture showing an example of the connectable state of three semiconductor chips in the semiconductor device shown in FIG. 2. And, FIG. 20 is a manufacturing flow picture showing an example of the assembly procedure of the semiconductor device of FIG. 2, FIG. 21 is a cross-sectional view showing an example of a wire-bonding state of the third stage chip in the assembly of the semiconductor device shown in FIG. 2, and FIG. 22 is a partially expanded cross-sectional view expanding and showing an example of the structure of the section A of FIG. 21.

The semiconductor device of Embodiment 1 shown in FIG. 1-FIG. 6 is a semiconductor package by which a plurality of semiconductor chips are laminated (are accumulated) on wiring substrate 7. Embodiment 1 takes up and explains SIP 8 by which two memory chips and one microcomputer chip 3 are laminated on wiring substrate 7 as an example of the semiconductor device.

When the structure of SIP 8 is explained, wiring substrate 7 which has main surface (a front surface, a chip mounting surface) 7a, and back surface 7b opposite to main surface 7a, the first semiconductor chip by which face-up mounting is done via first filmy adhesive 4 on main surface 7a of wiring substrate 7, the second semiconductor chip by which face-up mounting is done via second filmy adhesive 5 on the first semiconductor chip, and the third semiconductor chip by which face-up mounting is done via third filmy adhesive 6 on the second semiconductor chip are included. Further, a plurality of wires 9 which connect each surface electrode of the first, the second and the third semiconductor chip, and bonding lead (electrode) 7c of wiring substrate 7, sealing body 10 which does the resin seal of the first, the second, the third semiconductor chip, and a plurality of wires 9, and solder ball 11 which is formed in land 7g of back surface 7b of wiring substrate 7 and which are a plurality of external terminals are included.

In SIP 8, wire connection of all the chips is made to wiring substrate 7 for the reduction of cost. Therefore, all the chips are laminated by face-up mounting (mounting which turns the main surface of the semiconductor chip up, and mounting that the main surface of a semiconductor chip becomes identical direction to the main surface of a wiring substrate). Further, since all the chips are laminated by face-up mounting, in order to prevent the surface electrode of the main surface of the lower stage chip from becoming dirty with the extrusion to the outside of the die bonding material, all the chips have been adhered with the filmy adhesive called DAF. As shown in FIG. 4, the distance (L) of electrode pad 1c of the semiconductor chip (first memory chip 1) of the first stage and the end portion of the semiconductor chip (second memory chip 2) of the second stage is approaching as very short as L=about 170 μm, for example. Therefore, when a paste state binder is used as a die bonding material, the inconvenience that the paste state binder which overflowed from second memory chip 2 of the second stage will cover electrode pad 1c of first memory chip 1 of the first stage will happen.

The distance of the end portion of a semiconductor chip and bonding lead 7c formed on a wiring substrate also becomes near with the miniaturization of the semiconductor device. Therefore, when a paste state binder is used as a die bonding material, the inconvenience that the paste state binder which overflowed from the semiconductor chip of the first stage will cover bonding lead 7c on the wiring substrate will also happen. There is a problem of the die strength accompanying the thickness reduction of the semiconductor chip.

Therefore, by SIP 8, DAF is adopted as a die bonding material to the semiconductor chip of all the stages laminated from the problem of the extrusion of a die bonding material, and the die strength of a semiconductor chip.

That is, in SIP 8, wire bonding is performed with the ultrasonic thermocompression bonding method to all the chips, and die bonding by a filmy adhesive (DAF) is adopted. By this, all the chips are electrically connected to wiring substrate 7 with wire 9, respectively.

In the case of all the chips being wire bonding and face-up mounting, when the ease of striking of wire bonding is taken into consideration, it is preferred to mount a comparatively big semiconductor chip in the lower stage side, and to mount a comparatively small semiconductor chip in the upper row side.

In SIP 8 of Embodiment 1, first memory chip 1 which is a first semiconductor chip is for example, SDR-DRAM (Single Date Rate-Dynamic Random Access Memory) provided with a memory circuit which performs data transfer once between one cycle of an external clock signal, or DDR-DRAM (Double Date Rate-Dynamic Random Access Memory) provided with a memory circuit which performs data transfer synchronizing with both the rise and the drop of an external clock signal. As for first memory chip 1, the plane form which intersects the thickness consists of rectangular shape, and first memory chip 1 is a rectangle in Embodiment 1, for example, as shown in FIG. 7-FIG. 9. A plurality of electrode pads (surface electrode) 1c are formed along one two facing sides of four sides of the main surface 1a, and it has become a big semiconductor chip according to speeding up and realization-of-high-capacity correspondence.

Second memory chip 2 which is a second semiconductor chip is a FLASH memory for example. As shown in FIG. 10-FIG. 12, the plane form which intersects the thickness consists of rectangular shape, and is a rectangle in Embodiment 1, for example. A plurality of electrode pads (surface electrode) 2c are formed along one two facing sides of four sides of the main surface 2a, and it is a semiconductor chip smaller than first memory chip 1.

The third semiconductor chip is microcomputer chip 3 which has a data-processing function, and also performs transmission and reception of a signal with the outside of SIP 8 while performing transmission and reception of each memory chip and signal, in order to control operation of each memory chip. As shown in FIG. 16-FIG. 18, the plane form which intersects the thickness consists of rectangular shape, and is a square in Embodiment 1, for example. A plurality of electrode pads (surface electrode) 3c are formed along four sides of the main surface 3a, and an increasing of pin count and a narrowing of a pitch are done to the semiconductor chip. However, microcomputer chip 3 is a semiconductor chip smaller than both first memory chip 1 and second memory chip 2.

That is, in SIP 8, as shown in FIG. 2 and FIG. 5, the length of each semiconductor chip constitutes a relation of (first memory chip 1)>(second memory chip 2)>(microcomputer chip 3) to at least one direction of the X direction and the Y direction which constitute a right angle mutually of the arranging direction of electrode pad 3c of microcomputer chip 3.

So, in SIP 8, biggest first memory chip 1 is mounted in the bottom (first stage). As for microcomputer chip 3, electrode pads 3c are formed in the edge part of four sides of the main surface 3a by the increasing of pin count. Therefore, in consideration of doing wire bonding to all four sides, it is mounted in the highest stage (third stage). Further, second memory chip 2 smaller than first memory chip 1 is mounted in the middle (second stage).

Therefore, as shown in FIG. 4 and FIG. 6, back surface 1b of first memory chip 1 is connected with main surface 7a of wiring substrate 7 via first filmy adhesive 4. Back surface 2b of second memory chip 2 is connected with main surface 1a of first memory chip 1 via second filmy adhesive 5. Further, back surface 3b of microcomputer chip 3 is connected with main surface 2a of second memory chip 2 via third filmy adhesive 6.

Here, second memory chip 2 of the second stage has chip length shorter than microcomputer chip 3 of the third stage to the X direction along two facing sides of four sides of main surface 2a, as shown in FIG. 2-FIG. 4. Therefore, the both ends which have a side which intersects perpendicularly with the X direction in microcomputer chip 3 have structure which pushes out (overhangs) horizontally from second memory chip 2.

That is, in microcomputer chip 3 of the third stage, it has structure called an overhang in which near the two end portions which intersect perpendicularly with the X direction pushes out from second memory chip 2 of the middle. As shown in FIG. 4 in the case, the electrode pad 3c is arranged at pushing out part (part which pushed out) 3d of microcomputer chip 3. Wire bonding is performed to electrode pad 3c of this pushing out part 3d by the ultrasonic thermocompression bonding method.

Electrode pad 1c of first memory chip 1 of the bottom (first stage) is arranged at the pushing out part 3d lower part of microcomputer chip 3 of the highest stage (third stage).

In SIP 8 of Embodiment 1, the thickness of third filmy adhesive 6 is thinner than first filmy adhesive 4 and second filmy adhesive 5.

When an example of the thickness of each filmy adhesive is shown, first filmy adhesive 4 is about 251 μm, second filmy adhesive 5 is about 251 μm, and third filmy adhesive 6 is about 10 μm.

Thus, the problem of a wire bonding defect can be suppressed by making the thinnest thickness of third filmy adhesive 6 adhered on back surface 3b of microcomputer chip 3 of the highest stage (third stage) among the first, the second and the third filmy adhesives 4, 5, and 6. Since the thickness of DAF will be relatively thin even if third filmy adhesive 6 becomes soft under the influence of the heat in the wire-bonding step of microcomputer chip 3, microcomputer chip 3 becomes difficult to be depressed with the ultrasonic wave or load of wire bonding. That is, microcomputer chip 3 can be performed wire bonding in the stable state.

Here, as shown in FIG. 13-FIG. 15, in first memory chip 1 of the bottom, and second memory chip 2 of the second stage, they are mounted so that the wiring direction in wire bonding is different by 90°, and wire bonding is done. That is, first memory chip 1 is wired along the X direction, and, on the other hand, second memory chip 2 on first memory chip 1 is wired along Y direction which is different from this by 90°. Interference and contact of wires can be prevented by changing the wiring direction between the semiconductor chips laminated in this way.

As shown in FIG. 2, FIG. 3, and FIG. 5, microcomputer chip 3 of the third stage is performed wire bonding to four directions. Wires are formed outside to each of first memory chip 1 of the bottom, and second memory chip 2 of the second stage in the case. That is, bonding lead 7c on wiring substrate 7 is formed by four rows or five rows each side corresponding to each semiconductor chip.

In detail, as shown in FIG. 7 and FIG. 8, electrode pad 1c of first memory chip 1 of the bottom and first bonding lead (electrode) 7d of wiring substrate 7 corresponding to this are electrically connected by wire 9. First bonding lead 7d is formed by two rows near the first memory chip 1. In wiring substrate 7, a plurality of second bonding leads (electrode) 7e are formed in a line in two sides of a different direction from a first bonding lead 7d column. As shown in FIG. 13, these second bonding leads 7e, and electrode pad 2c of second memory chip 2 of the second stage are electrically connected by wire 9.

As shown in FIG. 16, a plurality of third bonding leads (electrode) 7f are formed in the edge part of main surface 7a of wiring substrate 7 in three rows. These third bonding leads 7f, and electrode pad 3c of microcomputer chip 3 of the third stage are electrically connected by wire 9. As shown in FIG. 3-FIG. 6, wire 9 connected to third bonding lead 7f is wired passing through the upper part of wire 9 connected to second bonding lead 7e or first bonding lead 7d.

As shown in FIG. 1, a plurality of bonding leads 7c are formed on the main surface 7a at wiring substrate 7. These bonding lead 7c is electrically connected with corresponding land 7g at the side of back surface 7b via through hole wiring 7h and internal wiring 7i in the substrate, and is connected to solder ball 11 which is an external terminal of SIP 8.

Each semiconductor chip (first memory chip 1, second memory chip 2, and microcomputer chip 3) is formed of silicon, for example, and various integrated circuits or circuits are formed in each semiconductor chip. Wire 9 is a gold wire, for example. Sealing body 10 is formed of the thermosetting epoxy resin etc., for example.

Next, the circuit operation in SIP 8 is explained using FIG. 19. Here, based on Embodiment 1, as memory chips, the case having first memory chip 1 in which DDR-DRAM is formed, second memory chip 2 in which the FLASH memory is formed, and microcomputer chip 3 which controls these operation is explained. However, about the number or the kind of memory chip, it is not restricted to this example.

As one of the main roles of microcomputer chip 3, there is work which changes the logical address for external interfaces (external address) into the physical address of DDR-DRAM or a FLASH memory in order to output and input data mediating between external LSI formed in the outside of the system, and first memory chips 1 and second memory chips 2 formed in the inside of the system, Therefore, microcomputer chip (ASIC) 3 is provided with the interface for DDR-DRAM, and the interface for FLASH memories.

When microcomputer chip 3 bears such a role, the electrode pad (pin) which forms an external interface is needed for microcomputer chip 3 except for the number of pins required for the interface between first memory chip 1 and second memory chip 2. Therefore, as for microcomputer chip 3, as compared with first memory chip 1 and second memory chip 2, the number of electrode pads (pin) 3c increases by the part of the number of pins needed for the external interface.

The data outputted via the external interface is changed into various information via external LSI, and is outputted to network equipment, human interface apparatus, etc.

On the other hand, since first memory chip 1 performs a data input output with external LSI via microcomputer chip 3, it is provided with the interface with microcomputer chip 3. However, first memory chip 1 has a clock (CK) terminal, and the clock enable terminal which controls the validity or the invalid of this clock terminal except for this. Current is applied to this CK terminal and data is transmitted (or received) synchronizing with the rise edge (or negative going edge) of the clock.

Second memory chip 2 is provided with the chip-select terminal (CE) except for the interface with microcomputer chip 3. Writing of the data to a FLASH memory or read-out is made possible by making this chip-select terminal valid or invalid. Further, in order to detect a specific address, the terminal (PRE) for power on reset is included.

According to the semiconductor device of Embodiment 1, third filmy adhesive 6 adhered on back surface 3b of microcomputer chip 3 of the highest stage (third stage) is formed most thinly among the filmy adhesives of each back surface of the semiconductor chip laminated by three stages. Hereby the influence to the ultrasonic wave and load of wire bonding by softening of third filmy adhesive 6 which happens with the heat can be reduced at the time of wire bonding of microcomputer chip 3.

Hereby the ultrasonic wave and load at the time of wire bonding travel to wire 9 easily and lowering of wire bonding property can be suppressed. As a result, the generation of wire peeling can be prevented and the generation of a wire bonding defect can be reduced.

In main surface 7a upper part of wiring substrate 7, irregularity is formed with bonding lead 7c, the dummy pattern, the resist layer (insulating film), etc. For example, irregularity is about 5 μm. Therefore, the comparatively thicker side of first filmy adhesive 4 arranged on main surface 7a is preferred. That is, thickness of first filmy adhesive 4 is set to 25 μm, and is made thicker than third filmy adhesive 6. Hereby irregularity of main surface 7a of wiring substrate 7 can be absorbed with first filmy adhesive 4, and, as a result, the planarizing of chip mounting can be maintained.

In SIP 8, each semiconductor chip is formed as thinly as possible for the thickness reduction of a package. As for the thickness of each semiconductor chip, for example, the thickness of first memory chip 1 of the bottom (first stage) is 100 μm, the thickness of second memory chip 2 of the middle (second stage) is 110 μm, and the thickness of microcomputer chip 3 of the highest stage (third stage) is 150 μm.

Thus, by forming more thinly than the chip of other stages the thickness of first memory chip 1 of the bottom (first stage), as shown in the P portion of FIG. 6, it can be prevented that wire 9 which was struck down from second memory chip 2 of the second stage towards the substrate, and the edge part of first memory chip 1 of the first stage contact and short-circuit (it is also called an area short circuit). Since the distance of wire 9 connected to second memory chip 2 becomes long especially when second memory chip 2 smaller than first memory chip 1 is laminated on this first memory chip 1 with a big area, it is easy to generate an area short circuit. However, the generation of the area short circuit can be prevented by forming thinly the thickness of first memory chip 1 of the bottom (first stage) like SIP 8 of Embodiment 1.

By making thickness of second memory chip 2 of the middle (second stage) thicker than first memory chip 1 of the bottom (first stage), as shown in FIG. 4, the height margin of wire 9 connected to first memory chip 1 of the first stage is securable. Hereby it can be prevented that wire 9 connected to first memory chip 1 of the first stage and back surface 3b of microcomputer chip 3 of the highest stage (third stage) contact.

Moreover, as for microcomputer chips 3 of the highest stage (third stage), wire 9 is three stage strike as shown in FIG. 6. Therefore, by making microcomputer chip 3 of the highest stage (third stage) thicker than first memory chip 1 of the bottom, and second memory chip 2 of the middle, as shown in the Q portion of FIG. 6, distance can be taken between wires, and the short circuit generation between wires can be prevented.

Further, the problem of a wire bonding defect can be more surely suppressed by making microcomputer chip 3 of the highest stage (third stage) thicker than first memory chip 1 of the bottom, and second memory chip 2 of the middle. This is because it is possible to do wire bonding of the semiconductor chip stably by making the thinnest third filmy adhesive 6 adhered to back surface 3b of microcomputer chip 3 of the highest stage (third stage) among the filmy adhesives of each back surface of the semiconductor chip laminated to three stages, as described above. However, especially when a part of microcomputer chips 3 (part in which electrode pad 3c is formed) of the highest stage (third stage) are laminated in the state (overhung state) pushing out from the chip (second memory chip 2) of the lower stage like Embodiment 1, the back surface side of the side in which electrode pad 3c is formed of microcomputer chip 3 of the highest stage (third stage) is what is called in a hollow state which is not supported at all. Therefore, even if the thickness of DAF is made thin relatively the die strength of the chip is falling in connection with the thickness reduction of a semiconductor chip, and the chip will bend according to the load in a wire-bonding step. As a result, the ultrasonic wave in a wire-bonding step becomes further difficult to be transmitted, wire bonding property gets worse, and wire peeling is caused. Then, the die strength of microcomputer chip 3 can be improved by making microcomputer chip 3 of the highest stage (third stage) thicker than first memory chip 1 of the bottom, and second memory chip 2 of the middle. From the above thing, the problem of the wire bonding defect under the influence of heat, an ultrasonic wave, and load in a wire-bonding step can be suppressed more surely.

Adjusting the thickness of all the semiconductor chips with the thickness of microcomputer chip 3 of the highest stage (third stage) is also considered for the measures against a wire bonding defect. However, since the thickness of a semiconductor device becomes thick in this case and dealing with thickness reduction becomes difficult, it is not desirable.

Second filmy adhesive 5 of the middle may make the thickness the same thickness as first filmy adhesive 4 of the bottom, and may make it the same thickness as third filmy adhesive 6 of the highest stage. However, it is more desirable to do to the thicker side, i.e., the same thickness as first filmy adhesive 4 of the bottom, since it is preferred to secure the height of second memory chip 2 of the middle as described above. Therefore, it is the same 251 μm as first filmy adhesive 4.

Next, the assembly procedure of the semiconductor device (SIP 8) of Embodiment 1 is explained using the flow diagram shown in FIG. 20.

First, chip mounting shown in Step S1 is performed. Here, first memory chip 1 of the bottom (first stage) is assembled (mounted) via first filmy adhesive 4 on main surface 7a of wiring substrate 7. In the case, the main surface 1a is turned up, and first memory chip 1 by which first filmy adhesive 4 was beforehand stuck on back surface 1b is mounted by face-up mounting.

Then, chip mounting shown in Step S2 is performed. Here, second memory chip 2 of the middle (second stage) is mounted via second filmy adhesive 5 on main surface la of first memory chip 1. In the case, the main surface 2a is turned up, and second memory chip 2 by which second filmy adhesive 5 was beforehand stuck on back surface 2b is mounted by face-up mounting.

Then, wire bonding shown in Step S3 is performed. That is, in the assembly of SIP 8, mounting of first memory chip 1 of the first stage and second memory chip 2 of the second stage is performed first. Then, before mounting microcomputer chip 3 of the third stage, wire bonding of first memory chip 1 of the first stage and second memory chip 2 of the second stage is performed continuously

That is, when microcomputer chip 3 of the third stage is mounted, there is a part (pushing out part 3d) currently protruded and overhung from second memory chip 2 of the second stage in microcomputer chip 3. This pushing out part 3d covers electrode pad 1c upper part of first memory chip 1 of the first stage. Therefore, wire bonding of first memory chip 1 will become impossible.

Therefore, in the assembly of SIP 8, mounting of first memory chip 1 of the first stage and second memory chip 2 of the second stage is performed. Then, before mounting microcomputer chip 3 of the third stage, wire bonding of first memory chip 1 of the first stage and second memory chip 2 of the second stage is performed continuously And mounting of microcomputer chip 3 of the third stage and wire bonding of microcomputer chip 3 are performed.

In wire bonding of Step S3, as shown in FIG. 13 and FIG. 14, electrode pad 1c of first memory chip 1, and first bonding lead 7d of wiring substrate 7 corresponding to this are connected with wire 9 (for example, gold wire), respectively All wire bonding performed in the assembly of SIP 8 is wire bonding of an ultrasonic thermocompression bonding method.

Then, wire bonding shown in Step S4 is performed. Here, as shown in FIG. 13 and FIG. 15, electrode pad 2c of second memory chip 2 and second bonding lead 7e of wiring substrate 7 corresponding to this are connected with wire 9, respectively

Then, chip mounting shown in Step S5 is performed. Here, microcomputer chip 3 of the highest stage (third stage) is mounted via third filmy adhesive 6 on main surface 2a of second memory chip 2. In the case, the main surface 3a is turned up, and microcomputer chip 3 with which third filmy adhesive 6 was beforehand stuck on back surface 3b is mounted by face-up mounting. Third filmy adhesive 6 is a DAF thinner than first filmy adhesive 4 and second filmy adhesive 5.

Then, wire bonding shown in Step S6 is performed. Here, as shown in FIG. 2, FIG. 3, and FIG. 5, electrode pad 3c of microcomputer chip 3 and third bonding lead 7f of wiring substrate 7 corresponding to this are connected with wire 9, respectively Wire bonding of microcomputer chip 3 is performed in the state where the wiring substrate on which the semiconductor chips are mounted has been arranged on stage 12 heated at about 220° C., as shown in FIG. 21 and FIG. 22. Hereby the temperature of each semiconductor chip rises up to about 170° C. Thus, electrode pad 3c arranged at the pushing out part 3d of microcomputer chip 3 and third bonding lead 7f of wiring substrate 7 are connected with wire 9 by capillary 13, applying heat.

Third filmy adhesive 6 adhered to back surface 3b of microcomputer chip 3 of the third stage is most thinly formed in the case. Therefore, the influence to the ultrasonic wave and load of wire bonding by softening of third filmy adhesive 6 which happens with the heat can be reduced at the time of wire bonding of microcomputer chip 3.

Hereby the ultrasonic wave and load at the time of wire bonding travel to wire 9 easily and lowering of wire bonding property can be suppressed. As a result, the generation of wire peeling can be prevented and the generation of wire bonding defect can be reduced.

Then, the resin seal shown in Step S7 is performed. Here, the resin seal of first memory chip 1, second memory chip 2, microcomputer chip 3, and a plurality of wires 9 is done with thermosetting epoxy resin etc., for example, and sealing body 10 is formed.

Then, ball attachment shown in Step S8 is performed. Here, a plurality of solder balls 11 used as an external terminal are joined to back surface 7b of wiring substrate 7, individual separation shown in Step S9 is performed further, and the assembly of SIP 8 is completed.

### Embodiment 2

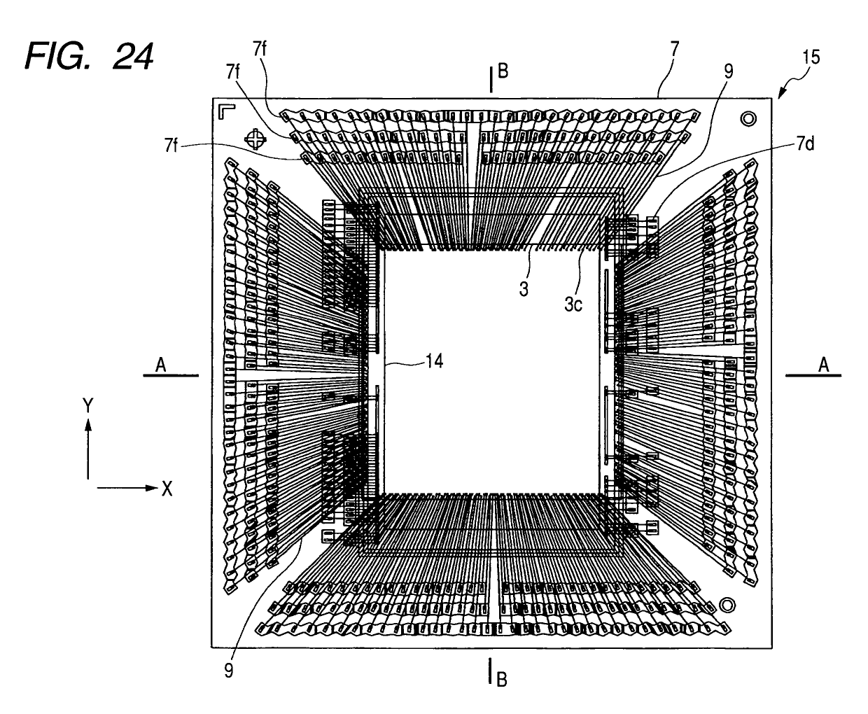

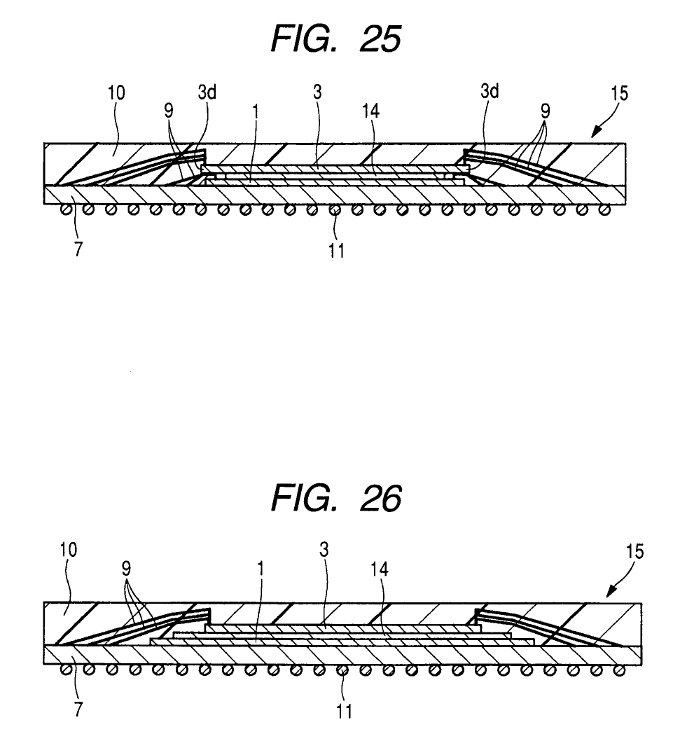

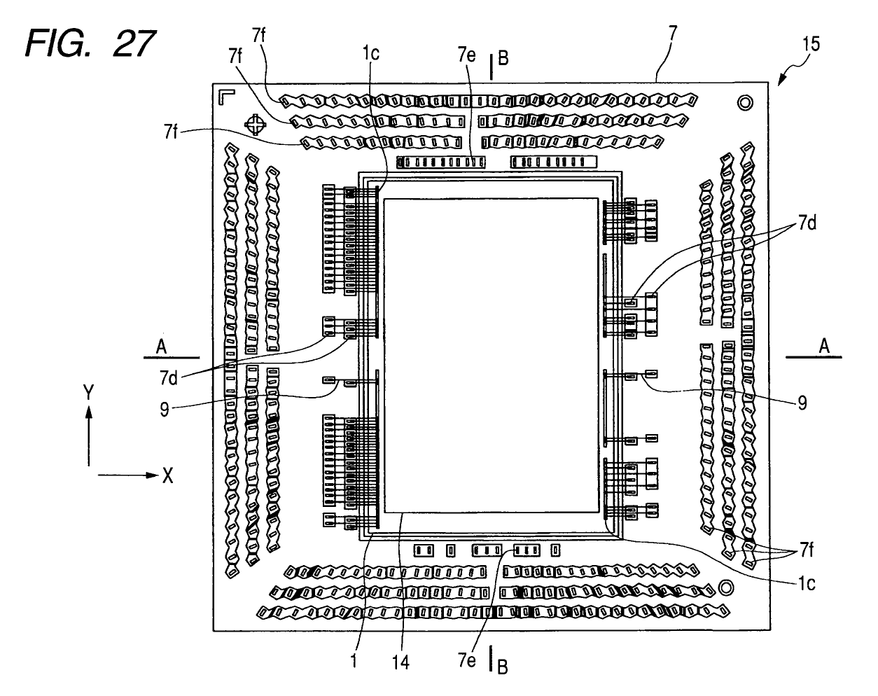

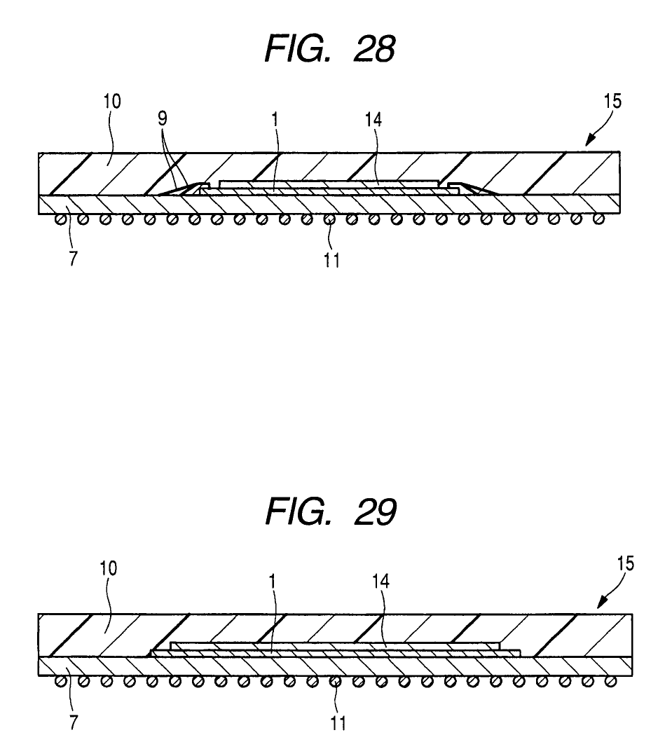

FIG. 23 is a cross-sectional view showing an example of the structure of the semiconductor device of Embodiment 2 of the present invention, FIG. 24 is a plan view penetrating a sealing body and showing an example of the fine structure of the semiconductor device shown in FIG. 23, FIG. 25 is a cross-sectional view showing an example of the structure cut along the A-A line of FIG. 24, FIG. 26 is a cross-sectional view showing an example of the structure cut along the B-B line of FIG. 24, and FIG. 27 is a plan view penetrating a sealing body and showing an example of a wiring state of the first stage chip in the semiconductor device shown in FIG. 24. Further, FIG. 28 is a cross-sectional view showing an example of the structure cut along the A-A line of FIG. 27, and FIG. 29 is a cross-sectional view showing an example of the structure cut along the B-B line of FIG. 27.

The semiconductor device of Embodiment 2 shown in FIG. 23-FIG. 26 is the semiconductor package by which a plurality of semiconductor chips are laminated (accumulated) on wiring substrate 7 like SIP 8 explained in Embodiment 1. However, the point of difference from SIP 8 is a point which transposed second memory chip 2 which is laminated in the middle (second stage) in SIP 8, and which is a second semiconductor chip to spacer chip 14 in which circuits, such as a semiconductor integrated circuit, are not formed.

Spacer chip 14 of Embodiment 2 should just have a spacer function for securing the height for wiring of the semiconductor chip of the first stage at least. Since it is not necessary to perform electric connection with wiring substrate 7 by wire connection, a surface electrode is not formed, either. However, the semiconductor chip with which circuits, such as a semiconductor integrated circuit, and a surface electrode are formed may be used as spacer chip 14.

Embodiment 2 takes up and explains SIP 15 by which one memory chip, one spacer chip 14, and one microcomputer chip 3 are laminated on wiring substrate 7 as an example of the semiconductor device.

That is, first memory chip (first semiconductor chip) 1 which is a semiconductor chip of the bottom (first stage) is mounted via first filmy adhesive 4 on wiring substrate 7. Spacer chip 14 is mounted via second filmy adhesive 5 on first memory chip 1. Further, microcomputer chip (third semiconductor chip) 3 which is a semiconductor chip of the highest stage (third stage) is mounted via third filmy adhesive 6. Each semiconductor chip is electrically connected to wiring substrate 7 by wire connection. Therefore, each semiconductor chip is mounted in the state of face up.

Further, SIP 15 has a plurality of wires 9 which connect the surface electrode of each of first memory chip 1 and microcomputer chip 3, and bonding lead 7c of wiring substrate 7, sealing body 10 which does the resin seal of first memory chip 1, spacer chip 14, microcomputer chip 3, and a plurality of wires 9, and a plurality of solder balls 11 formed on land 7g of back surface 7b of wiring substrate 7.

Also in SIP 15, the thickness of third filmy adhesive 6 of the third stage is thinner than first filmy adhesive 4 of the first stage, and second filmy adhesive 5 of the second stage like SIP 8 of Embodiment 1.

Also in SIP 15, spacer chip 14 has chip length shorter than microcomputer chip 3 of the third stage to the X direction, as shown in FIG. 24 and FIG. 25. Therefore, SIP 15 has structure where the both ends which have a side which intersects perpendicularly with the X direction push out (overhang) horizontally from spacer chip 14 in microcomputer chip 3.

That is, in microcomputer chip 3 of the third stage, it has structure in which near the two end portions which intersect perpendicularly with the X direction pushes out from spacer chip 14 of the middle and which is called an overhang. As shown in FIG. 23 and FIG. 25 in the case, the electrode pad 3c is arranged at pushing out parts (part which pushed out) 3d of microcomputer chip 3. Wire bonding is performed to electrode pad 3c of this pushing out part 3d by the ultrasonic thermocompression bonding method.

As shown in FIG. 23, electrode pad 1c of first memory chip 1 of the bottom (first stage) is arranged at the pushing out part 3d lower part of microcomputer chip 3 of the highest stage (third stage).

As shown in FIG. 26, spacer chip 14 is longer than microcomputer chip 3 to the Y direction which constitutes a right angle to the X direction. As shown in microcomputer chip 3 at FIG. 24, electrode pads 3c are formed in four sides of the main surface 3a, and this makes longer than microcomputer chip 3 the Y direction so that the overhang of the microcomputer chip 3 of the third stage is not done if possible in spacer chip 14.

In SIP 15, as shown in FIG. 27-FIG. 29, a surface electrode is not formed in spacer chip 14 of the second stage, therefore wire connection is not made, either. About first memory chip 1 of the first stage, a plurality of electrode pads 1c are formed only in two sides which face of the main surface 1a like SIP 8 of Embodiment 1. These electrode pads 1c are electrically connected to first bonding lead 7d of wiring substrate 7 by wire 9.

About the other structures of SIP 15 of Embodiment 2, since it is the same as that of SIP 8 of Embodiment 1, the duplicate explanation is omitted.

Also in SIP 15 of Embodiment 2, third filmy adhesive 6 adhered to back surface 3b of microcomputer chip 3 of the highest stage (third stage) is the thinnest among first, second and third filmy adhesives 4, 5, and 6. Hereby the influence to the ultrasonic wave and load of wire bonding by softening of third filmy adhesive 6 which takes place with the heat can be reduced at the time of wire bonding of microcomputer chip 3.

Hereby the ultrasonic wave and load at the time of wire bonding travel to wire 9 easily and lowering of wire bonding property can be suppressed. As a result, the generation of wire peeling can be prevented and the generation of a wire bonding defect can be reduced.

About the other effects acquired by the semiconductor device (SIP 15) of Embodiment 2, since it is the same as that of SIP 8 of Embodiment 1, the duplicate explanation is omitted.

As for the assembly of SIP 15 of Embodiment 2, since spacer chip 14 is mounted at chip mounting of Step S2 and wire bonding to spacer chip 14 is not performed in the manufacturing flow of SIP 8 of Embodiment 1 shown in FIG. 20, the assembly of SIP 15 is shown by omitting wire bonding of Step S4. Therefore, the duplicate explanation is omitted.

In the foregoing, the present invention accomplished by the present inventors is concretely explained based on above embodiments, but the present invention is not limited by the above embodiments, but variations and modifications may be made, of course, in various ways in the limit that does not deviate from the gist of the invention.

For example, the Embodiment 1 explained the case where two memory chips and one microcomputer chip were laminated on wiring substrate 7. However, as for the number of laminations of a memory chip, any pieces are sufficient, if it is two or more.

The present invention is suitable for the electronic device which has a plurality of laminated semiconductor chips.

What is claimed is:

1. A semiconductor device, comprising:
a wiring substrate having a main surface, and a back surface opposite to the main surface;
a plurality of semiconductor chips mounted by laminating over the main surface of the wiring substrate;
a filmy adhesive adhered to a back surface of each of the semiconductor chips;
a plurality of wires connecting a surface electrode of each of the semiconductor chips with an electrode of the wiring substrate; and
a plurality of external terminals formed over the back surface of the wiring substrate;
wherein a filmy adhesive adhered to a back surface of a semiconductor chip of a highest stage is the thinnest among filmy adhesives of a back surface of each of the semiconductor chips.

2. A semiconductor device according to claim 1, wherein
a filmy adhesive adhered to a back surface of the semiconductor chip of the highest stage is thinner than a filmy adhesive adhered to a back surface of a semiconductor chip of a bottom.

3. A semiconductor device according to claim 1, wherein
a thickness of a semiconductor chip of a bottom is thinner than the semiconductor chip of the highest stage.

4. A semiconductor device according to claim 1, wherein
the semiconductor chip of the highest stage has a pushing out part which projects from a semiconductor chip of a lower stage, and a surface electrode of a semiconductor chip of a bottom is arranged at a pushing out part lower part of the semiconductor chip of the highest stage.

5. A semiconductor device according to claim 1, wherein
the semiconductor chip of the highest stage is a microcomputer chip, and a semiconductor chip of a bottom is a memory chip.

6. A semiconductor device according to claim 5, wherein
the memory chip has a memory circuit which performs data transfer once between one cycle of an external clock signal, or a memory circuit which performs data transfer synchronizing with both of rise and drop of an external clock signal.

7. A semiconductor device according to claim 1, wherein
the semiconductor chip of the highest stage has a pushing out part which projects from a semiconductor chip of a lower stage, and a surface electrode of the semiconductor chip of the highest stage is formed in the pushing out part.

8. A semiconductor device according to claim 1, wherein
each surface electrode of the semiconductor chips is connected to the wire by wire bonding of an ultrasonic thermocompression bonding method.

9. A semiconductor device, comprising:
a wiring substrate having a main surface, and a back surface opposite to the main surface;
a first semiconductor chip by which face-up mounting is done via a first filmy adhesive over the main surface of the wiring substrate;
a second semiconductor chip by which face-up mounting is done via a second filmy adhesive over the first semiconductor chip;
a third semiconductor chip by which face-up mounting is done via a third filmy adhesive over the second semiconductor chip;
a plurality of wires connecting a surface electrode of each of the first, the second and the third semiconductor chip with an electrode of the wiring substrate; and
a plurality of external terminals formed over the back surface of the wiring substrate;
wherein a thickness of the third filmy adhesive is thinner than the first and the second filmy adhesive.

10. A semiconductor device according to claim 9, wherein
the third filmy adhesive is thinner than the first filmy adhesive.

11. A semiconductor device according to claim 9, wherein
a thickness of the first semiconductor chip is thinner than the third semiconductor chip.

12. A semiconductor device according to claim 9, wherein
the third semiconductor chip has a pushing out part which projects from the second semiconductor chip of the lower stage, and a surface electrode of the first semiconductor chip is arranged at a pushing out part lower part of the third semiconductor chip.

13. A semiconductor device according to claim 9, wherein
surface electrodes are formed in the third semiconductor chip along four sides of the main surface, and a length of each semiconductor chip has a relation of a first semiconductor chip>a second semiconductor chip>a third semiconductor chip to one direction of an X direction and a Y direction which constitute a right angle mutually among arranging directions of surface electrodes of the third semiconductor chip.

14. A semiconductor device, comprising:
a wiring substrate having a main surface, and a back surface opposite to the main surface;
a first semiconductor chip by which face-up mounting is done via a first filmy adhesive over the main surface of the wiring substrate;
a spacer chip mounted via a second filmy adhesive over the first semiconductor chip;
a third semiconductor chip by which face-up mounting is done via a third filmy adhesive over the spacer chip;
a plurality of wires connecting a surface electrode of each of the first and the third semiconductor chip with an electrode of the wiring substrate; and
a plurality of external terminals formed over the back surface of the wiring substrate;
wherein a thickness of the third filmy adhesive is thinner than the first and the second filmy adhesive.

15. A semiconductor device according to claim 14, wherein
the third film-like adhesive is thinner than the first film-like adhesive.

16. A semiconductor device according to claim 14, wherein
the third semiconductor chip has a pushing out part which projects from the spacer chip of the lower stage, and a surface electrode of the first semiconductor chip is arranged at a pushing out part lower part of the third semiconductor chip.

17. A semiconductor device according to claim 14, wherein
surface electrodes are formed in the third semiconductor chip along four sides of the main surface, the spacer chip is shorter than the third semiconductor chip to one side of an X direction and a Y direction which constitute a right angle mutually among arranging directions of surface electrodes of the third semiconductor chip, and the spacer chip is longer than the third semiconductor chip to the other of the X direction and the Y direction.
